(19) United States
(12) Patent Application Publication
(10) Pub. No.: US 2026/0173942 A1
(43) Pub. Date: Jun. 18, 2026

(54) PASTE COMPOSITION FOR PRESSURELESS SINTER BONDING, BONDING METHOD USING THE SAME AND ELECTRONIC COMPONENT PREPARED USING THE SAME

(71) Applicants: Cha Hwan HWANG, Namyangju-si (KR); KD MTEC Co., Ltd., Pyeongtaek-si (KR)

(72) Inventors: Bum Gyu BAEK, Asan-si (KR); Hyung Min CHA, Asan-si (KR); Kyu Ho YEON, Bucheon-si (KR); Cha Hwan HWANG, Namyangju-si (KR); Jin Woo PARK, Pyeongtaek-si (KR)

(21) Appl. No.: 19/414,290

(22) Filed: Dec. 10, 2025

(30) Foreign Application Priority Data
Dec. 12, 2024 (KR) 10-2024-0184573
Nov. 13, 2025 (KR) 10-2025-0171343

(51) Int. Cl. H10W 72/30; H10W 72/00; H10W 90/00

(52) U.S. Cl. CPC H10W 72/352; H10W 72/07331; H10W 90/734

(57) ABSTRACT

Embodiments direct to a paste composition for pressureless sinter bonding, a bonding method using the same and an electronic component prepared using the same, and more particularly to a paste composition for pressureless sinter bonding, including: silver nanoparticles; silver nanoparticle aggregates; and a mixed solvent including an alcohol-based solvent and an ether-based solvent, a bonding method including the operations of applying a paste composition for pressureless sinter bonding of the present disclosure to a bonding surface and heating a bonding object at a temperature of 150 to 300° C. under an atmospheric pressure of 1 atm while bonding the bonding object to the bonding surface, and an electronic component manufactured by bonding using a paste composition for pressureless sinter bonding of the present disclosure.

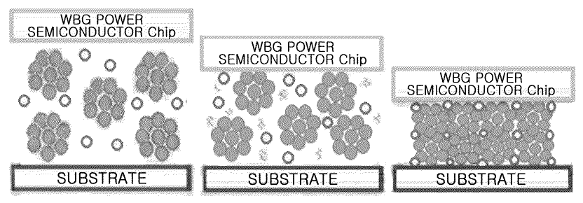

### CROSS-REFERENCE TO RELATED APPLICATION(S)

This application claims benefit of priority to Korean Patent Application No. 10-2024-0184573 filed on Dec. 12, 2024 and Korean Patent Application No. 10-2025-0171343 filed on Nov. 13, 2025, in the Korean Intellectual Property Office, the disclosure of which are incorporated herein by reference in their entireties.

### BACKGROUND

### 1. Field

The present disclosure relates to a paste composition for pressureless sinter bonding, a bonding method using the same and an electronic component prepared using the same, and more particularly to a paste composition for pressureless sinter bonding, able to be applied with high efficiency without requiring pressure condition, a bonding method using the same and an electronic component prepared using the same.

### 2. Description of Related Art

Semiconductor chips using silicon carbide (Sic) and gallium nitride (GaN) have features having the ability to operate at temperatures of 300° C. or higher. However, when semiconductor chips operate at high temperatures, conventional solders and Pb-free solders are unsuitable due to remelting and reduced high-temperature reliability. Accordingly, a paste for sinter bonding in which fine metal powder particles having excellent heat resistance and thermal/electric conductivity are dispersed in a solvent has been used.

Furthermore, with the growth of eco-friendly electric vehicles and renewable energy markets, demand for high-power and high-efficiency power semiconductors has increased. These power semiconductor devices must support higher power densities and switching frequencies while ensuring the reliability of high-performance electronic modules, but solder alloys are melted when conventional Pb-free solders or solders are used. This is unsuitable for use in high-temperature operating environment of a high-performance power semiconductor chip using silicon carbide (SiC), gallium nitride (GaN), or the like, in bonded form.

In order to address this issue, when manufacturing power semiconductor modules using Wide Bandgap (WBG) power semiconductors (e.g., SiC or GaN), a pressure-sintered bonding material utilizing solid diffusion bonding of nano-sized metal powder particles is used to replace a solder paste, which has low thermal conductivity and melting point characteristics, which typically requires a pressurized thermocompression process. For example, when using a pressurized thermocompression process, as described in Japanese Patent No. 4247800, there are issues with reduced production efficiency and yield. In particular, damage to semiconductor devices, such as chip damage caused by pressurization, may occur, resulting in an increase in a defect rate.

Accordingly, there is a need for high-speed sinter bonding materials under non-pressurized processing conditions that may exhibit high reliability in high-temperature operating environments for Wide Bandgap (WBG) power semiconductors used in electric vehicles and AI data centers, and that may improve productivity by simplifying the existing pressure sintering process and may reduce the defect rate caused by chip damage.

### SUMMARY

One aspect of the present disclosure provides a paste composition for pressureless sinter bonding that does not require pressurization and utilizes only thermal energy.

Another aspect of the present disclosure provides a bonding method under pressureless conditions using the paste composition for sinter bonding of the present disclosure.

Another aspect of the present disclosure provides an electronic component manufactured using the paste composition for sinter bonding of the present disclosure.

According to an aspect of the present disclosure, a paste composition for pressureless sinter bonding, including: silver nanoparticles; silver nanoparticle aggregates; and a mixed solvent including an alcohol-based solvent and an ether-based solvent is provided.

According to another aspect of the present disclosure, a bonding method including the operations of applying a paste composition for pressureless sinter bonding of the present disclosure to a bonding surface and heating a bonding object at a temperature of 150 to 300° C. under an atmospheric pressure of 1 atm while bonding the bonding object to the bonding surface is provided.

According to another aspect of the present disclosure, an electronic component manufactured by bonding using a paste composition for pressureless sinter bonding of the present disclosure.

According to the present disclosure, a paste composition for sinter bonding, capable of sintering at high speed under pressureless conditions is provided, so that the process may be simplified through a pressureless sintering process. Furthermore, it is expected that the paste composition for sinter bonding of the present disclosure has excellent continuous printing properties to have excellent printing efficiency and viscosity specific recovery rate, and may prevent contraction and cracking during sinter bonding, and may be widely applied to fields such as power semiconductors that require high reliability due to excellent physical properties such as shear strength.

### BRIEF DESCRIPTION OF DRAWINGS

The above and other aspects, features, and advantages of the present disclosure will be more clearly understood from the following detailed description, taken in conjunction with the accompanying drawings, in which:

FIGURE shows example of applying the paste composition for pressureless sinter bonding of the present disclosure to a substrate and a semiconductor bonding surface, which is a schematic representation of a state after sintering (right) according to the passage of time from the application (left) to the right.

### DETAILED DESCRIPTION

Hereinafter, preferred embodiments of the present disclosure will be described with reference to the attached drawings. However, the embodiments of the present disclosure may be modified in various other forms, and the scope of the present disclosure is not limited to the embodiments described below.

According to the present disclosure, a paste composition capable of bonding using a pressureless sintering process is provided.

More specifically, the paste composition for pressureless sinter bonding of the present disclosure includes: silver nanoparticles; silver nanoparticle aggregates; and a mixed solvent including an alcohol-based solvent and an ether-based solvent.

In the present disclosure, the silver nanoparticles are monodisperse silver particles, i.e., individual silver nanoparticles, and may have a particle size of 10 nm to 300 nm, for example, 20 nm to 280 nm, and considering dispersion performance based on the surface energy of the nanoparticles, a particle size of 30 nm or greater is preferable, and considering shear strength based on the specific surface area of the nanoparticles, a particle size of 200 nm or less is preferable. When the particle size of the silver nanoparticles falls below the above-described range, the silver nanoparticles may be difficult to handle and may have difficulty ensuring dispersion within the paste, and when dispersion is not properly secured, printability may deteriorate due to reduced dispersion, and bonding strength may decrease during sintering, and when the particle size exceeds the above-described range, the bonding strength may be deteriorated during final sintering-bonding with the silver nanoparticle aggregates of the present disclosure, or a printing surface leveling and a printing thickness deviation during paste printing may increase.

Meanwhile, the shape of the silver nanoparticles is not particularly limited and may be at least one of spherical, plate-like, or dendritic shapes. For example, the silver nanoparticles may be spherical.

The silver nanoparticle aggregate of the present disclosure is a conjugate formed by the aggregation of a plurality of silver nanoparticles, and for example, the silver nanoparticle aggregate may be the conjugate by the aggregation of silver nanoparticles having a particle size of 10 nm to 300 nm, and a particle size of the silver nanoparticle aggregate may range from 0.5 μm to 30 μm, for example, from 1 μm to 20 μm. When a size of the silver nanoparticle aggregate is less than 0.5 μm, this exhibits surface energy similar to that of silver nanoparticles, resulting in poor dispersion performance and reduced shear strength, and when the size of the silver nanoparticles aggregate exceeds 30 μm, activation energy of the nanoparticles decreases, resulting in a tendency for shear strength to decrease.

Thus, the silver nanoparticle aggregate of the present disclosure may ensure excellent uniformity after final sintering, as shown in FIGURE, by utilizing the conjugate formed by the aggregation of silver nanoparticles of the present disclosure.

For example, the silver nanoparticle aggregates may be obtained by reacting silver nanoparticles with a nitrate salt at 50 to 100° C. for 1 to 3 hours, and in this case, the nitrate salt may be ammonium nitrate, barium nitrate, iron nitrate, zinc nitrate, copper nitrate, sodium nitrate, potassium nitrate, calcium nitrate, magnesium nitrate, and the like, and the nitrate salt may be at least one selected from the group consisting of a metal nitrate having a nitrate group in Groups 1 and 2, sodium nitrate, potassium nitrate, magnesium nitrate, calcium nitrate, strontium nitrate, manganese nitrate as second, third, fourth or fifth period transition metal nitrates of barium nitrate, aluminum nitrate, iron (II) nitrate, cobalt (II) nitrate, nickel (II) nitrate, copper (II) nitrate, zinc nitrate, gallium nitrate, palladium (II) nitrate, silver nitrate, cadmium nitrate, indium nitrate, bismuth nitrate, and nitrates of metals corresponding to element numbers 58 to 71 in the lanthanide series.

Furthermore, the silver nanoparticle aggregates used in the present disclosure are preferably surface-treated with a surface-treating agent including at least one selected from the group consisting of fatty acids having a carbon chain length of C₅ to C₂₆, including saturated and/or unsaturated fatty acids, e.g., fatty acids having a carbon chain length of C₅ to C₂₀, C₁₂₋₂₂ long-chain alkanethiols, such as long-chain alkanethiols having a carbon chain length of C₁₂₋₁₈, and amine derivatives, and the saturated fatty acids having a carbon chain length of C₅ to C₂₆ may include, for example, hexanoic acid, ethylhexanoic acid, dodecanoic acid, hexadecanoic acid, oleic acid, dodecanethiol, stearic acid, lauric acid, ethylamine, tetraethylenepentaamine and oleylamine, caprylic acid, caprylic acid, lauric acid, myristic acid, palmitic acid, stearic acid, arachidic acid, behenic acid, lignoceric acid, and cerotic acid, and the unsaturated fatty acids including at least one C═C double bond having a carbon chain length of C₅ to C₂₆ may include, for example, linoleic acid, oleic acid, and arachidic acid, and an amine derivative, in which a carboxylic acid functional group of the fatty acid is replaced with a primary amine group (NH₂), may be at least one selected from an aliphatic primary amine group consisting of hexylamine, octylamine, decylamine, dodecylamine, hexadecylamine, octadecylamine, and oleylamine, and may include an alkanethiol, such as dodecanethiol, a long-chain alkanethiol having a carbon chain length of C₁₂-C₂₂.

The surface-treated silver nanoparticle aggregate of the present disclosure may have a specific surface area of greater than 1 m²/g and less than or equal to 2 m²/g, for example, 1.2 to 1.99 m²/g. Meanwhile, the silver nanoparticles of the present disclosure may have a specific surface area of 1.7 to 1.9 m²/g.

Meanwhile, the solvent used in the paste composition of the present disclosure is a mixed solvent including an alcohol solvent and an ether solvent. The alcohol solvent and the ether solvent are preferably included in a weight ratio of 1:3 to 3:1, for example, 1:1 to 2:1, and when the weight ratio exceeds the above-described range, printing performance and efficiency tend to deteriorate.

Furthermore, the mixed solvent used in the paste composition of the present disclosure may further include an acetate solvent, and in this case, the mixed solvent may include the alcohol solvent, the ether solvent, and the acetate solvent in a weight ratio of 80 to 98:1 to 10:1 to 10, for example, 84 to 96:2 to 8:2 to 8.

The paste composition for pressureless sinter bonding of the present disclosure may include, based on the total weight of the paste composition, 0.1 to 10 wt % of silver nanoparticles having a particle size of 10 nm to 300 nm; 60 to 80 wt % of silver nanoparticle aggregates having a particle size of 0.5 μm to 30 μm; and a remaining mixed solvent including an alcohol-based solvent and an ether-based solvent in a weight ratio of 1:3 to 3:1, and for example, the mixed solvent may be included in an amount of 10 to 40 wt % based on the total weight of the paste composition.

When the silver nanoparticle content is below the above-described range, the sinter bonding performance may be degraded, and when the content thereof exceeds the above-described range, the tack of the paste increases, resulting in poor printing performance. When the silver nanoparticle aggregate content is below the above-described range, sintering delays, poor printing performance, and sintering shrinkage may occur, and when the content exceeds the above-above-described range, the sinter bonding performance may be degraded.

Metal powder particles other than silver nanoparticles may be added. For example, the metal powder particles may be one or more metal powder particles selected from copper (Cu), silver-coated copper (Ag Coated Cu), gold (Au), platinum (Pt), nickel (Ni), tin (Sn), aluminum (Al), zinc (Zn), bismuth (Bi), indium (In), phosphorus (P), and silicon (Si), or two or more alloy powder particles selected therefrom.

An alcohol-based solvent that may be used in the present disclosure may be at least one selected from α-Terpineol, 1,2-Propanediol, 1,3-Butanediol, 2-Methyl-1,3-Propanediol, Pine oil alcohol (85%), Triethylene Glycol, 1-Decanol, 1-Octanol, Propylene Glycol, Glycerol, Trimethylolpropane, Ethylene Glycol, Diethylene Glycol, Triethylene Glycol, Cyclohexanol, Lauryl Alcohol, Oleyl Alcohol, Nonyl Alcohol, and Dodecanol. The alcohol-based solvent may include, preferably, 40 to 80% of terpene alcohol and/or glycol alcohol based on the total weight of the alcohol solvent, and may include at least one acyclic aliphatic saturated alcohol (alkanol).

For example, the alcohol solvent may be a mixed alcohol solvent including α-terpineol, 1,2-propanediol, 1,3-butanediol, 2-methyl-1,3-propanediol, and 1-decanol, and such components may be mixed in a weight ratio of 4:2:1:1:1, and further, when triethylene glycol is additionally used, the components α-terpineol, triethylene glycol, 1,2-propanediol, 1,3-butanediol, 2-methyl-1,3-propanediol, and 1-decanol may be mixed in a weight ratio of 2:2:1:1:1:1.

An ether solvent that may be used in the present disclosure may be at least one selected from Diethylene Glycol Butyl Ether, Diethylene Glycol Mono-n-Hexyl Ether, Diethylene Glycol Monomethyl Ether, Diethylene Glycol Monophenyl Ether, Tri(Propylene Glycol) Butyl Ether, Diethylene Glycol Dibutyl Ether, Triethylene Glycol Monobutyl Ether, Diethylene Glycol Monobenzyl Ether, Diethylene Glycol Butyl Methyl Ether, Triethylene Glycol Dimethyl Ether, Dipropylene Glycol n-Propyl Ether, Ethylene Glycol Monophenyl Ether, Isopropyl Ether, and Tetraethylene Glycol Dimethyl Ether. For example, a mixed ether solvent obtained by mixing diethylene glycol monobutyl ether, diethylene glycol mono-n-hexyl ether, diethylene glycol monophenyl ether, and triethylene glycol monobutyl ether may be used as the ether solvent, and such components may be mixed in a weight ratio of 1:1:1:1.

The acetate-based solvent that may be used in the present disclosure may be at least one selected from propylene glycol diacetate, dipropylene glycol methyl ether acetate, propylene glycol monomethyl ether acetate, butyl acetate, methyl acetate, ethyl acetate, 4-tert-butylcyclohexyl acetate, 2-butoxyethyl acetate, and ethylene glycol monobutyl ether acetate. For example, a mixed acetate solvent obtained by mixing propylene glycol diacetate and dipropylene glycol methyl ether acetate may be used as the acetate solvent, and in this case, such components may be mixed in a 1:1 weight ratio.

Furthermore, the paste composition for pressureless sintering of the present disclosure may further include at least one thickener selected from the group consisting of an epoxy and curing agent mixture, an organic thixotropic agent, and an inorganic thixotropic agent.

In this case, the epoxy having an EEW (equivalent weight/g) of 100 to 6000 may be used, and for example, at least one of a low-molecular-weight epoxy having an EEW (equivalent weight/g) of 100 to 4000, a medium-molecular-weight epoxy having an EEW (equivalent weight/g) of 400 to 1000, and a high-molecular-weight epoxy having an EEW (equivalent weight/g) of 1000 to 400 may be used, and preferably, a low-molecular-weight epoxy may be used.

More specifically, the epoxy one having two or more epoxy groups per molecule may be used. Either one type may be used, or two or more types may be used in combination. Specific examples of such epoxy resins may include those obtained by the condensation of epichlorohydrin with polyhydric phenols such as bisphenols or polyhydric alcohols, and examples thereof may include glycidyl ether-type epoxy resins such as bisphenol A, brominated bisphenol A, hydrogenated bisphenol A, bisphenol F, bisphenol S, bisphenol AF, biphenyl, naphthalene, fluorene, novolac, phenol novolac, orthocresol novolac, tris(hydroxyphenyl)methane, and tetraphenylethylene. Other examples may include glycidyl ester epoxy resins obtained by condensation of epichlorohydrin with carboxylic acids such as phthalic acid derivatives or fatty acids, glycidylamine epoxy resins obtained by reacting epichlorohydrin with amines, cyanuric acids, or hydantoins, and epoxy resins modified by various methods, but the present disclosure is not limited thereto. Specifically, bisphenol epoxy resins and glycidylamine epoxy resins are preferably used, and thereamong, bisphenol A, bisphenol F, bisphenol AF, and glycidylamine epoxy resins are preferably used.

A curing agent may include a resol-type phenol resin, a novolac-type phenol resin, a curing catalyst such as acid anhydrides, tertiary amines and triphenyl phosphines, an anionic polymerization curing agent such as dicyandiamide, hydrazines and aromatic diamines, and organic peroxides, but the present disclosure is not limited thereto, and for example, anhydride-based and/or aromatic diamine-based epoxy curing agents may be used. The epoxy curing agents may be used alone or in combination of two or more thereof. The anhydride-based epoxy curing agent may be, for example, at least one selected from 3 or 4-methyl-1,2,3,6-tetrahydrophthalic anhydride, methyl tetrahydrophthalic anhydride, nadic methyl anhydride, 3,3′,4,4′-benzophenone tetracarboxylic dianhydride, pyromellitic dianhydride, and hexahydro-4-methylphthalic anhydride, and the aromatic diamine-based epoxy curing agent may be, for example, at least one selected from imidazole, aromatic amine, phenylenediamine, benzidine, diaminostilbene, m-xylylene diamine, and p-xylylene diamine.

The amount of the curing agent is not limited and may be appropriately determined depending on the type and amount of the epoxy resin. For example, the epoxy and curing agent may be mixed and used in a weight ratio of 5:5 to 9:1, for example, 6:5 to 7:3.

Meanwhile, the organic thixotropic agent may be selected from the group consisting of: a wax-based thixotropic agent such as carnauba wax, microcrystalline wax, montan wax, and Fischer-Tropsch wax; an amine-based thixotropic agent such as stearylamine, oleylamine and dodecylamine; and a cellulose-based thixotropic agent such as hydroxypropyl cellulose (HPC), carboxymethyl cellulose (CMC) and methyl cellulose, and may be for example, at least one selected from amide wax, polyethylene wax (PE wax), cetylamine, ethyl cellulose, and polytetrafluoroethylene wax (PTFE wax).

Meanwhile, the inorganic thixotropic agent may be selected from the group consisting of: a silica-based agent such as colloidal silica and precipitated silica; a clay-based material including hexadecyl bentonite (Hectorite) and montmorillonite; an carbonate-based material including magnesium carbonate (MgCO₃) and strontium carbonate (SrCO₃); and a silicate-based material including palygorskite and talc; and may be for example, at least one selected from fumed silica, bentonite, calcium carbonate (CaCO₃), and sepiolite.

In this case, the thickener may be included in an amount of 0.1 wt % to 15 wt %, for example, 5 wt % to 10 wt %, based on the total weight of the paste composition, and when the amount thereof is below the above-described range, the thickener effect may be insufficient, and when the amount thereof exceeds the above-described range, organic substances within the paste may deteriorate sinter bonding performance. Meanwhile, increasing the amount of inorganic thixotropic agent may interfere with solid diffusion bonding between metal powder particles, and unlike organic substances, the inorganic thixotropic agent has a high decomposition temperature, which may lead to a decrease in sinter bonding performance as the amount increases.

Furthermore, the paste composition for pressureless sintering of the present disclosure may further include an additive including at least one selected from the group consisting of an organic dispersant, a nonionic surfactant, and an aliphatic compound including a carboxylic acid and a fatty acid. For example, the aliphatic compound may be at least one selected from the group consisting of palmitic acid, malonic acid, oleic acid, glutaric acid, picolinic acid, sebacic acid, hexanoic acid, ascorbic acid, citric acid, polyacrylic acid, lauric acid, and maleic acid, and may be amines such as trialkanolamines, for example, alkanols having 1 to 5 carbon atoms, and acyclic aliphatic unsaturated diols such as halogenated alkenyl diols may also be used.

Furthermore, the additive may further include a nonionic surfactant and an organic dispersant.

The organic dispersant may be at least one selected from a high-molecular-weight block copolymer, an alkyl ammonium salt of a high-molecular-weight copolymer, an acrylate copolymer, an unsaturated polyamine amide, a low-molecular-weight acidic polyester salt, an acidic copolymer, an alkyl ammonium salt of a block copolymer including an acidic group, methoxypropyl acetate, and a low-molecular-weight unsaturated polycarboxylic acid. More specifically, the high-molecular-weight block copolymer may be Pluronic-based (EO-PO-EO) polymers such as Pluronic F68, Pluronic L64 and Pluronic P85, Tetronic-based polymers such as Tetronic 1107 and Tetronic 304, and Hypermer-based polymers such as Hypermer KD1 and Hypermer KD3; the alkyl ammonium salt of high molecular weight copolymers may be Polyquaternium-based polymers such as Polyquaternium-10 and Polyquaternium-7, and Cetrimonium Methosulfate; the acrylate copolymer may be carbomers such as Carbomer 940 and Carbopol ETD 2020, a Disperbyk-based copolymer such as Disperbyk 110, Disperbyk 111 and Disperbyk 163, and a Rheovis-based copolymer such as Rheovis AS1125 and Rheovis PU1191; the unsaturated polyamine amide may be a Versamid-based product such as Versamid 125 and Versamid 140; the low-molecular-weight acidic polyester salt may be a Solsperse-based product such as Solsperse 20000, Solsperse 30000 and Efka 7700 (BASF); the acid copolymer may be polyacrylic acid, a Dispex-based product, and the like; the alkyl ammonium salt of block copolymers having acidic groups may be block copolymers of PEG and PAA, a Dispex Ultra-based product, and the like; and the low-molecular-weight unsaturated polycarboxylic acids may be PASA (Polyaspartic Acid), Solsperse 46000, and the like.

Meanwhile, the nonionic surfactant may be an alkyl alkoxylate-based surfactant such as C₁₁-C₁₅ alcohol alkoxylates, a polyoxyethylene-based surfactant such as polyoxyethylene alkyl ether, polyoxyethylene alkylphenol ether and polyoxyethylene sorbitan ester, poloxamers (Pluronic) such as Pluronic having an EO-PO-EO block copolymer structure, glycerin derivatives such as glyceryl monostearate (GMS) and glyceryl monolaurate (GML), sorbitol derivatives such as sorbitan esters, and alkyl glucosides such as decyl glucoside and lauryl glucoside.

The additive may be included in an amount of 0.1 wt % to 5 wt %, for example, 0.1 wt % to 4 wt %, based on the total weight of the paste composition, and when the amount is below the above-described range, the additive effect may be insufficient, and when the amount exceeds the above-described range, the organic content in the paste may increase, resulting in a decrease in sintering performance.

According to another aspect of the present disclosure, provided is a bonding method including the operations of applying a paste composition for the pressureless sinter bonding of the present disclosure to a bonding surface, and heating a bonding object at a temperature of 150 to 300° C. under an atmospheric pressure of 1 atm while bonding the bonding object to the bonding surface.

In the case of using the paste for the pressureless sinter bonding of the present disclosure, because pressurization is unnecessary, problems such as reduced production efficiency and yield due to the pressurization process can be avoided. Furthermore, there is no problem with chip damage due to pressure.

According to another aspect of the present disclosure, an electronic component manufactured by bonding using the paste composition for pressureless sintering of the present disclosure is provided, and the electronic component may be a semiconductor, for example, a power semiconductor.

More specifically, the semiconductor device is formed by bonding a semiconductor element to a substrate serving as an element support member using the paste composition described above. Specifically, the paste composition is used as a die-attach material, and the semiconductor element and the substrate are bonded and fixed via such a die-attach material.

Here, the semiconductor element is not particularly limited as long as this is a known semiconductor element, and examples thereof include transistors and diodes. Furthermore, examples of the semiconductor element may include light-emitting elements such as LED. Furthermore, the type of light-emitting element is not particularly limited, and may be for example, a nitride semiconductor such as InN, AlN, GaN, InGaN, AlGaN or InGaAlN formed as a light-emitting layer on a substrate using a MOCVD method or the like.

Additionally, the element support member may be formed of materials such as copper, copper-plated copper, PPF (pre-plated lead frame), glass epoxy, or ceramics.

By using the die-attach material, the semiconductor element may be attached to a substrate that is not metal-plated.

For example, the operation of applying the composition onto a power semiconductor substrate is not limited to roller, brush, or spray application, and stencil or screen-printing are also possible.

The silver nanoparticles and silver nanoparticle aggregates may be melted and bonded by sintering.

In the present disclosure, “melting” is understood to encompass not only complete dissolution of the entire powder or particles, but also partial melting, such as fluidity occurring on the powder or particle surface, and surface premelting. The sintering may be performed at a temperature suitable for sintering the silver nanoparticles, and for example, the sintering may be performed at a temperature of 150 to 300° C., and more specifically, by performing heating to 200 to 250° C.

Specifically, the composition of the present disclosure may sufficiently melt and bond without pressure or under pressures of 15 MPa or less or 10 MPa or less during sintering.

The present disclosure will be described in more detail below through specific examples. The following examples are merely illustrative examples to aid understanding of the present disclosure and are not intended to limit the scope of the present disclosure.

### EXAMPLES

### 1. Preparation of a Paste Composition for Pressureless Sinter Bonding

### (1) Preparation of Silver Nanoparticles

A silver nitrate solution is prepared by stirring a mixture including 30 wt % of silver nitrate (AgNO₃) in ethylene glycol (EG). A polyvinylpyrrolidone solution is prepared by stirring a mixture including 20 wt % of polyvinylpyrrolidone (PVP, M.W.=40,000) in ethylene glycol. The polyvinylpyrrolidone solution is heated to 120° C. in a reactor equipped with a reflux condenser, stirred, and maintained at the temperature. The silver nitrate (AgNO₃) solution is injected into the prepared polyvinylpyrrolidone solution using a syringe pump at a rate of 10 ml/min for 30 minutes and maintained for 18 hours. The obtained mixed solution is then cooled to room temperature and centrifuged to separate individual silver nanoparticles from the solution. The separated individual silver nanoparticles were redispersed in ethanol and then a precipitate was formed by adding an excess of acetone. This was then centrifuged again, and the supernatant was removed. This process was repeated three times, after which the individual silver nanoparticles were redispersed in distilled water (DW) to prepare a silver nanoparticle solution.

The individual silver nanoparticles thus obtained were referred to as Preparation Example 1. The size of the single silver particles was determined by varying the PVP concentration as shown in Table 1.

TABLE 1

| | PVP | Average particle | Tap |
|---|---|---|---|
| | Concentration | size of Ag single | Density |
| Division | (wt %) | particles (nm) | (g/cm³) |
| Preparation | 30 | 30 | 4.5 g/cm³ |
| Example 1 | | | |
| Preparation | 25 | 50 | 3.2 g/cm³ |
| Example 2 | | | |
| Preparation | 20 | 100 | 2.6 g/cm³ |
| Example 3 | | | |
| Preparation | 15 | 150 | 2.1 g/cm³ |
| Example 4 | | | |
| Preparation | 10 | 250 | 1.7 g/cm³ |
| Example 5 | | | |

As shown in Table 1, the Ag nanoparticle size was confirmed to decrease as the PVP concentration increased, in which case an average particle size thereof was measured as the particle size using SEM images.

The individual silver particles having an average diameter of 30 to 100 nm were used to prepare the paste composition for pressureless sintering of the present disclosure.

### (2) Preparation of Silver Nanoparticle Aggregates

### 1) Preparation of Silver Nanoparticle Aggregates

In order to remove PVP from a surface of the silver nanoparticles dispersed in distilled water (D.W.) in Preparation Example 2 obtained by item (1) above, a 50 wt % citric acid aqueous solution was added little by little to the silver nanoparticle solution and continuously stirred. The stirring speed was 300 rpm. A citric acid solution was added until the silver nanoparticle solution turns dark gray, and the obtained solution was centrifuged to recover silver nanoparticles free of PVP. Additionally, the silver nanoparticles were washed three times with distilled water and then redispersed in distilled water. The redispersed silver nanoparticles were heated and stirred at 50 to 100° C. while adding ammonia water to adjust the pH to 10-11. Ammonium nitrate (NH₄NO₃) was then added as a coagulant at a rate of 5 parts by weight per 100 parts of silver nanoparticles, followed by heating and stirring for 1 hour. The coagulated nanoparticles were then recovered by centrifugation, washed three times with distilled water, and dried at 60° C.

Table 2 below presents a specific surface area and average particle size (D50) measurements of silver nanoparticle aggregates prepared under various reaction conditions, measured using a wet particle size analyzer. (The grinding conditions after preparation of the aggregates were the same.)

TABLE 2

| | | Reaction | Reaction | | Average | Specific |
|---|---|---|---|---|---|---|
| | | Temperature | Time | | particle size | Surface Area |
| Division | Coagulant | (° C.) | (hr) | Form | (μm) | (BET-m²/g) |
| Preparation | NH₄NO₃ | 55 | 0.5 | Aggregate | 0.38 | 2.42 |
| Example 6 | | | | | | |
| Preparation | NH₄NO₃ | 55 | 1 | Aggregate | 0.83 | 1.92 |
| Example 7 | | | | | | |
| Preparation | NH₄NO₃ | 55 | 2 | Aggregate | 0.92 | 1.97 |
| Example 8 | | | | | | |
| Preparation | NH₄NO₃ | 55 | 4 | Aggregate | 6.83 | 0.94 |
| Example 9 | | | | | | |
| Preparation | NH₄NO₃ | 55 | 6 | Aggregate | 10.76 | 0.51 |
| Example 10 | | | | | | |
| Preparation | NH₄NO₃ | 55 | 8 | Aggregate | 22.45 | 0.43 |
| Example 11 | | | | | | |
| Preparation | NH₄NO₃ | 55 | 10 | Aggregate | 29.81 | 0.41 |
| Example 12 | | | | | | |
| Preparation | NH₄NO₃ | 55 | 12 | Aggregate | 33.64 | 0.27 |
| Example 13 | | | | | | |
| Preparation | NH₄NO₃ | 65 | 0.5 | Aggregate | 0.35 | 2.27 |
| Example 14 | | | | | | |
| Preparation | NH₄NO₃ | 65 | 1 | Aggregate | 0.88 | 1.9 |
| Example 15 | | | | | | |
| Preparation | NH₄NO₃ | 65 | 2 | Aggregate | 1.04 | 1.85 |
| Example 16 | | | | | | |
| Preparation | NH₄NO₃ | 65 | 4 | Aggregate | 6.35 | 1.12 |
| Example 17 | | | | | | |
| Preparation | NH₄NO₃ | 65 | 6 | Aggregate | 12.43 | 0.60 |
| Example 18 | | | | | | |
| Preparation | NH₄NO₃ | 65 | 8 | Aggregate | 21.67 | 0.45 |
| Example 19 | | | | | | |
| Preparation | NH₄NO₃ | 65 | 12 | Aggregate | 40.39 | 0.21 |
| Example 20 | | | | | | |
| Preparation | NH₄NO₃ | 75 | 2 | Aggregate | 1.37 | 1.78 |
| Example 21 | | | | | | |
| Preparation | NH₄NO₃ | 85 | 2 | Aggregate | 1.55 | 1.65 |
| Example 22 | | | | | | |
| Preparation | NH₄NO₃ | 95 | 2 | Aggregate | 1.87 | 1.4 |
| Example 23 | | | | | | |
| Comparative | None | | No post- | Monodisperse | 0.12 | 2.88 |
| Preparation | | | processing | | | |
| Example 1 | | | | | | |
| Comparative | NH₄NO₃ | 65 | 0.5 | Monodisperse | 0.48 | 2.3 |
| Preparation | | | | | | |
| Example 2 | | | | | | |
| Comparative | None | 65 | 2 | Monodisperse | 0.35 | 2.41 |
| Preparation | | | | | | |
| Example 3 | | | | | | |

As a result, it was confirmed that the higher the temperature during the manufacturing process, the stronger the cohesion of the aggregates, but when the coagulant, ammonium nitrate (NH₄NO₃) was added at less than 5 parts by weight per 100 parts by weight of silver nanoparticles, the aggregates were not formed smoothly.

### 2) Surface Treatment

An organic acid, long-chain alkanethiol, or amine derivative equivalent to 20 parts by weight per 100 parts by weight of the silver nanoparticle aggregates as a surface treatment agent was added to a container including the silver nanoparticle aggregate powder particles obtained in Manufacturing Example 16 among the silver nanoparticle aggregates of item (2) 1) above, and then, the mixture was heated and stirred at 65° C. for 1 hour at 300 rpm to allow the organic acid to be adsorbed onto the silver nanoparticle aggregates. The pH of the solution was maintained at 8-9, and heating and stirring were maintained for 10 to 240 minutes. The solution after the reaction was cooled to room temperature, and after a supernatant was removed from the solution, the silver nanoparticle aggregates was washed five times with distilled water, and finally filtered using a centrifuge, followed by drying at 60° C. for 15 hours. The specific types of surface treatment agents used in each manufacturing example are shown in Table 3.

Meanwhile, the results obtained by performing a surface treatment using the same process as: for the aggregates, except that silver nanoparticles dispersed in distilled water (D.W.) obtained in item (1) above were used instead of the aggregates, are also shown in Table 3 as a comparative manufacturing example.

TABLE 3
Types of Surface Treatment Agents

| | Silver Powder | Types of Surface Treatment |
|---|---|---|
| Division | Form | Agents |
| Preparation | Aggregate | Acetic acid |
| Example 24 | | |
| Preparation | Aggregate | Butyric acid |
| Example 25 | | |
| Preparation | Aggregate | Hexanoic acid |
| Example 26 | | |
| Preparation | Aggregate | Ethyl hexanoic acid |
| Example 27 | | |
| Preparation | Aggregate | Dodecanoic acid |
| Example 28 | | |
| Preparation | Aggregate | Hexadecanoic acid |
| Example 29 | | |
| Preparation | Aggregate | Oleic acid |
| Example 30 | | |
| Preparation | Aggregate | dodecanethiol |
| Example 31 | | |
| Preparation | Aggregate | Oleyl amine |
| Example 32 | | |
| Preparation | Aggregate | Octyl amine |
| Example 33 | | |
| Preparation | Aggregate | Palmitic acid |
| Example 34 | | |
| Comparative | Monodisperse | No post-processing |
| Preparation | | |
| Example 4 | | |
| Comparative | Monodisperse | dodecanthiol |
| Preparation | | |
| Example 5 | | |
| Comparative | Monodisperse | Oleyl amine |
| Preparation | | |
| Example 6 | | |
| Comparative | Aggregate | No post-processing |
| Preparation | | |
| Example 7 | | |

### (3) Preparation of Paste Composition

5 wt % of the silver nanoparticles of Preparation Example 2 and 72 wt % of the silver nanoparticle aggregates of Preparation Example 30 were mixed with 9.5 wt % of a mixed solvent consisting of an alcohol solvent, an ether solvent and an acetate solvent, 6 wt % of epoxy, 4 wt % of a curing agent, and 3.5 wt % of an additive, thus preparing a paste composition.

The alcohol solvent used was a mixed alcohol solvent including α-terpineol, triethylene glycol, 1,2-propanediol, 1,3-butanediol, 2-methyl-1,3-propanediol, and 1-decanol in a weight ratio of 4:2:1:1:1, the ether solvent used was a mixed ether solvent including diethylene glycol monobutyl ether, diethylene glycol mono-n-hexyl ether, diethylene glycol monophenyl ether, and triethylene glycol monobutyl ether in a weight ratio of 1:1:1:1, and the acetate solvent used was a mixed solvent including propylene glycol diacetate and dipropylene glycol methyl ether acetate in a weight ratio of 1:1.

Furthermore, for the thickener, bisphenol F epoxy in which an EEW (equivalent weight/g) is 170, and MTHPA (3 or 4-Methyl-1,2,3,6-Tetrahydrophthalic Anhydride) were mixed at a weight ratio of 8:2 for epoxy and curing agent. As for the additive, BYK 111 was used as an organic dispersant, an alcohol alkoxylate was used as a nonionic surfactant, and at least one of palmitic acid, malonic acid, maleic acid, oleic acid, dodecanethiol, or trans-2,3-dibromo-2-butene-1,4-diol was used as an activator.

The paste composition thus prepared corresponds to a paste composition of Example 5 below.

Meanwhile, Comparative Examples 3 to 6 in Table 4 below include only 75 wt % of the silver nanoparticles of Comparative Preparation Examples 4 to 7 and do not include silver nanoparticle aggregates, in which 11.5 wt % of solvent, 6 wt % of epoxy, 4 wt % of curing agent, and 3.5 wt % of additives were mixed and used.

In this case, dispersion was performed in three stages: a first dispersion of using a planetary mixer at a speed of 100 to 1,000 rpm for 5 to 30 minutes; a second dispersion of using a 3 roll-mill at a speed of 50 to 400 rpm and a roller gap of 3 to 50 μm for 10 to 40 minutes; and a third dispersion of using a paste mixer at a speed of 700 to 1,000 rpm for 1 to 5 minutes.

Dispersity of the prepared paste composition was measured using a Fineness of Grind Gauge (FOG) device, and the surface gloss was visually inspected. The dispersity was expressed as a numerical value confirmed by FOG measurement results and the gloss was evaluated as Bad if the surface was rough and had many bubbles, evaluated as Normal if the surface had few bubbles but was still rough, evaluated as Good if the surface was moist and bubble-free, and evaluated as Excellent if the surface was moist and had high gloss enough to reflect light.

Table 4 shows the dispersity and surface gloss of the pastes according to the type of surface treatment agent in Table 3.

TABLE 4
Dispersity and Surface Gloss of Pastes according
to Types of Surface Treatment Agents

| | | | FOG | |
|---|---|---|---|---|
| | | Types of | measurement | |
| | Silver | Surface | Region of | |
| | nanoparticle | Treatment | Dispersity | Surface |
| Division | Aggregate | Agents | of Paste (μm) | Gloss |
| Comparative | Preparation | Acetic acid | 11 | Bad |
| Example 1 | Example 24 | | | |
| Comparative | Preparation | Butyric acid | 10 | Bad |
| Example 2 | Example 25 | | | |
| Inventive | Preparation | Hexanoic acid | 11 | Normal |
| Example 1 | Example 26 | | | |
| Inventive | Preparation | Ethyl | 7 | Normal |
| Example 2 | Example 27 | hexanoic acid | | |
| Inventive | Preparation | Dodecanoic | 8 | Good |
| Example 3 | Example 28 | acid | | |
| Inventive | Preparation | Hexadecanoic | 8 | Good |
| Example 4 | Example 29 | acid | | |
| Inventive | Preparation | Oleic acid | 2 | Good |
| Example 5 | Example 30 | | | |
| Inventive | Preparation | dodecanthiol | 2 | Excellent |
| Example 6 | Example 31 | | | |
| Inventive | Preparation | Oleyl amine | 3 | Good |
| Example 7 | Example 32 | | | |
| Inventive | Preparation | Octyl amine | 2 | Normal |
| Example 8 | Example 33 | | | |
| Inventive | Preparation | Palmitic acid | 3 | Excellent |
| Example 9 | Example 34 | | | |
| Comparative | Comparative | No post- | 13 | Bad |
| Example 3 | Preparation | processing | | |
| | Example 4 | | | |
| Comparative | Comparative | dodecanthiol | 2 | Excellent |
| Example 4 | Preparation | | | |
| | Example 5 | | | |
| Comparative | Comparative | Oleyl amine | 3 | Excellent |
| Example 5 | Preparation | | | |
| | Example 6 | | | |
| Comparative | Comparative | No post- | 11 | Bad |
| Example 6 | Preparation | processing | | |
| | Example 7 | | | |

As shown in Table 4, it may be confirmed that the surface treatment of silver nanoparticle aggregates affected the dispersity of the paste composition, and the silver nanoparticle aggregates of Preparation Examples 30 to 34 exhibited the best dispersity.

Furthermore, changes in the dispersity of the pastes according to varying surface treatment agent content are shown in Table 5. More specifically, particles surface-treated using the same process as Preparation Examples 30 to 34, which exhibited excellent dispersibility, were used, but the dispersity of the pastes prepared with the composition of Example 5 was measured using particles prepared with varying surface treatment agent content.

TABLE 5
Dispersity of Pastes according to Surface Treatment Agent Content

| | | Parts by weight | | |
|---|---|---|---|---|
| | | per 100 parts by | FOG | |
| | | weight of | measurement | |
| | | silver | Region of | |
| | | nanoparticle | Dispersity of | Surface |
| | Division | aggregate | Paste (μm) | Gloss |
| Inventive | Preparation | 1 | 1 | Excellent |
| Example | Example 30- | | | |
| 10 | 2 | | | |
| Inventive | Preparation | 0.5 | 2 | Good |
| Example 5 | Example 30 | | | |
| Inventive | Preparation | 0.1 | 5 | Good |
| Example | Example 30- | | | |
| 11 | 3 | | | |
| Inventive | Preparation | 1 | 1 | Excellent |
| Example | Example 31- | | | |
| 12 | 2 | | | |
| Inventive | Preparation | 0.5 | 2 | Excellent |
| Example 6 | Example 31 | | | |
| Inventive | Preparation | 0.1 | 2 | Excellent |
| Example | Example 31- | | | |
| 13 | 3 | | | |
| Inventive | Preparation | 1 | 2 | Good |
| Example | Example 32- | | | |
| 14 | 2 | | | |
| Inventive | Preparation | 0.5 | 3 | Good |
| Example 7 | Example 32 | | | |
| Inventive | Preparation | 0.1 | 7 | Good |
| Example | Example 32- | | | |
| 15 | 3 | | | |
| Inventive | Preparation | 1 | 2 | Normal |
| Example | Example 33- | | | |
| 16 | 2 | | | |
| Inventive | Preparation | 0.5 | 2 | Normal |
| Example 8 | Example 33 | | | |
| Inventive | Preparation | 0.1 | 3 | Normal |
| Example | Example 33- | | | |
| 17 | 3 | | | |
| Inventive | Preparation | 1 | 3 | Excellent |
| Example | Example 34- | | | |
| 18 | 2 | | | |
| Inventive | Preparation | 0.5 | 3 | Good |
| Example 9 | Example 34 | | | |
| Inventive | Preparation | 0.1 | 8 | Good |
| Example | Example 34- | | | |
| 19 | 3 | | | |

As shown in Table 5, it may be confirmed that the surface treatment of silver nanoparticle aggregates affects the dispersion in the paste composition, and all pastes prepared in the inventive examples of the present disclosure exhibited excellent dispersion.

### 2. Evaluation of Physical Properties of Paste Compositions Depending on the Type of Solvent

In order to evaluate screening printing performance of the paste compositions prepared by Inventive Example 5 among the paste compositions prepared in item 1. (3) above, and the paste compositions prepared based on Inventive Example 5 but varying only the type of solvent from Example 5, as shown in Table 6, screen-printing was performed under the following conditions.

### * Screen-Printing Conditions

Thickness: 30 μm
Speed: 30 mm/s
Plate Separation Speed: 0.5 mm/s
S/Q Angle: 55

### * Pressureless Sintering Process Conditions

Sintering: 250° C., 30 min, Oven drying in an air atmosphere

In this case, the printing efficiency was measured by measuring the volume fraction of the printed shape using 3D image analysis after screen-printing, and shear strength was measured using typical Die shear measurements. The results are shown in Table 6.

In Table 6, an acetate solvent, an alcohol solvent, and an ether solvent were the same mixed acetate solvent, the same mixed alcohol solvent, and the same mixed ether solvent as those used in the preparation of the paste composition in item 1. (3) above, a mixed solvent in which cyclohexanol and isophorone are mixed at a weight ratio of 1:1 was used.

TABLE 6
Printing Efficiency and Shear Strength by Solvent Type

| | | | Ace- | | | |
|---|---|---|---|---|---|---|
| | Alcohol - | Ether - | tate - | Ketone- | Printing | Shear |
| | based | based | based | based | Effi- | Strength |
| Division | solvent | solvent | solvent | solvent | ciency | (MPa) |
| Inventive | 25 | 75 | — | — | 91% | 25.8 |
| Example 20 | | | | | | |
| Inventive | 55 | 45 | — | — | 97% | 22.8 |
| Example 21 | | | | | | |
| Inventive | 75 | 25 | — | — | 98% | 28.5 |
| Example 22 | | | | | | |
| Inventive | 90 | 5 | 5 | — | 99% | 36.3 |
| Example 5 | | | | | | |
| Inventive | 100 | — | — | — | 99% | 33.6 |
| Example 23 | | | | | | |
| Comparative | — | 100 | — | — | 92% | 12.7 |
| Example 7 | | | | | | |
| Comparative | — | — | 100 | — | 86% | 7.8 |
| Example 8 | | | | | | |
| Comparative | — | — | — | 100 | 72% | 3.4 |
| Example 9 | | | | | | |
| Comparative | 25 | 25 | 25 | 25 | 91% | 16.9 |
| Example 10 | | | | | | |

As shown in Table 6, since an alcohol-based solvent is generally highly polar, dispersibility and printability thereof are excellent because the alcohol-based solvent has good compatibility with other ingredients, and an ether-based solvent possesses high affinity for metals and improving shear strength, but has low thickening properties, and since the ether-based solvent has high affinity for metal substrates, which may form low tack, resulting in impairing the rolling properties of the paste composition. The acetate-based solvent possesses poor compatibility and low thickening properties, but provides excellent bonding performance (shear strength) by creating a reducing atmosphere. A ketone-based solvent, on the other hand, exhibits high room-temperature vapor pressures and low boiling points (B.P.), which may result in poor continuous printability of the paste composition and reduced printing efficiency.

Specifically, it may be confirmed that the use of the surface treatment agents of the present disclosure improved the dispersity of the paste, maintains excellent printability, and the surface activation of the silver nanoparticles particles facilitated solid diffusion bonding between the silver nanoparticles during paste sintering, thereby enhancing shear strength. However, when a significantly large amount of surface treatment agents is used, the surface treatment agent may not be fully decomposed within the paste during sintering and may remain as residual organic matter, resulting in hindering solid diffusion bonding between silver nanoparticles and potentially reducing shear strength.

### 3. Printing Process Suitability of Paste Compositions Including Additional Ingredients

### 1) Viscosity Recovery Rate, Print SPI (Thickness Deviation), and Shear Strength According to Thickener

The viscosity recovery rate, print SPI (Thickness Deviation), and shear strength of the paste compositions prepared by Inventive Example 5 among the paste compositions prepared in item 1. (3) above, and the paste compositions prepared based on Inventive Example 5 but varying only the type of thickener from Inventive Example 5, as shown in Table 7, were confirmed. Ethyl cellulose was used as the cellulose-based thickener, cetyl amine was used as the amine-based thickener, bentonite was used as the inorganic thixotropic agent, and amide wax was used as the organic thixotropic agent, and for the epoxy and curing agent, a mixture of bisphenol F epoxy with an EEW (equivalent weight/g) of 170 and MTHPA as the curing agent was used at a weight ratio of 8:2.

TABLE 7
Viscosity recovery rate, Printing SPI, and Shear Strength
according to the type and content of thickener.

| | | | Inorganic- | Organic- | Epoxy | Viscosity | Print SPI | | |
|---|---|---|---|---|---|---|---|---|---|
| | Cellulose- | Amine- | based | based | and | specific | (Left and | | Shea |
| | based | based | thixotropic | thixotropic | curing | recovery | right | | Strength |
| Division | thickener | thickener | agent | agent | agent | rate | deviation) | | (MPa) |
| Inventive | — | — | — | — | 100 | ± 8% | 8 | μm | 36.3 |
| Example 5 | | | | | | | | | |
| Inventive | — | — | — | 10 | 90 | ±7% | 7 | μm | 35.6 |
| Example 24 | | | | | | | | | |
| Inventive | — | — | — | 25 | 75 | ±5% | 6 | μm | 36.1 |
| Example 25 | | | | | | | | | |
| Inventive | — | — | — | 50 | 50 | ±4% | 6 | μm | 28.7 |
| Example 26 | | | | | | | | | |
| Inventive | — | — | — | 70 | 30 | ±5% | 5 | μm | 26.5 |
| Example 27 | | | | | | | | | |
| Inventive | — | — | — | 85 | 15 | ±3% | 6 | μm | 20.3 |
| Example 28 | | | | | | | | | |
| Inventive | — | — | — | 90 | 10 | ±3% | 6 | μm | 20.5 |
| Example 29 | | | | | | | | | |
| Comparative | — | — | — | 100 | — | ±2% | 4 | μm | 12.2 |
| Example 11 | | | | | | | | | |
| Inventive | 25 | 25 | 25 | 25 | 25 | ±6% | 9 | μm | 17.8 |
| Example 30 | | | | | | | | | |
| Comparative | — | — | 100 | — | — | ±11% | 4 | μm | 11.2 |
| Example 12 | | | | | | | | | |
| Comparative | — | 100 | — | — | — | ±10% | 9 | μm | 12.7 |
| Example 13 | | | | | | | | | |
| Comparative | 100 | — | — | — | — | ±8% | 12 | μm | 10.4 |
| Example 14 | | | | | | | | | |

* Each value is a weight percent based on the total weight of the thickener.

When the compositions of the inventive examples of the present disclosure were used, all shear strengths were good at 10 MPa or more, and specifically, when an epoxy and a curing agent were used in a certain amount or more, excellent shear strength was shown.

### 2) Shear Strength According to Additives

The shear strength of the paste composition prepared by Inventive Example 5 among the paste compositions prepared in item 1. (3) above, and the paste compositions prepared based on Inventive Example 5 but varying only the type of additives from Example 5 were confirmed.

The additives were added in the amounts shown in Table 8, and alcohol alkoxylate was used as a nonionic surfactant, and BYK 111 was used as an organic dispersant.

TABLE 8
Shear Strength According to Additive Type and Content

| | | | | | | | | Trans 2,3- | |
|---|---|---|---|---|---|---|---|---|---|
| | | | | | | | | dibromo- | Shear |
| | organic | nonionic | palmitic | malonic | maleic | oleic | | 2-butene- | Strength |
| Division | dispersant | surfactant | acid | acid | acid | acid | dodecanthiol | 1,4-diol | (MPa) |
| Comparative | 100 | | | | | | | | 15.4 |
| Example 15 | | | | | | | | | |
| Comparative | | 100 | | | | | | | 14.8 |
| Example 16 | | | | | | | | | |
| Inventive | | | 100 | | | | | | 29.4 |
| Example 31 | | | | | | | | | |
| Inventive | | | | 100 | | | | | 18.1 |
| Example 32 | | | | | | | | | |
| Inventive | | | | | 100 | | | | 28.4 |
| Example 33 | | | | | | | | | |
| Inventive | | | | | | 100 | | | 27.5 |
| Example 34 | | | | | | | | | |
| Inventive | | | | | | | 100 | | 12.7 |
| Example 35 | | | | | | | | | |
| Inventive | | | | | | | | 100 | 25.6 |
| Example 36 | | | | | | | | | |
| Inventive | 75 | | 25 | | | | | | 31.3 |
| Example 37 | | | | | | | | | |
| Inventive | 75 | | | | 25 | | | | 32.2 |
| Example 38 | | | | | | | | | |
| Inventive | 75 | | | | | 25 | | | 31.4 |
| Example 39 | | | | | | | | | |
| Inventive | 75 | | | | | | | 25 | 30.7 |
| Example 40 | | | | | | | | | |
| Inventive | 75 | | | | 15 | 10 | | | 34.4 |
| Example 41 | | | | | | | | | |
| Inventive | 75 | | | | | 15 | | 10 | 36.3 |
| Example 5 | | | | | | | | | |
| Inventive | 75 | | | | 15 | | | 10 | 33.6 |
| Example 42 | | | | | | | | | |

* Each value is a weight percent (wt %) based on the total weight of the additive.

As shown in Table 8, dispersants that may improve dispersion performance and organic acid-based activators may be added together to improve the shear strength of sintered bonding materials, and at least two types of activators may be used.

### 4. Evaluation of Physical Properties of Paste Compositions According to the Contents of Individual Silver Particles and Agglomerates

With respect to the paste compositions prepared by Inventive Example 5 among the paste compositions prepared in item 1. (3) above, and the paste compositions prepared based on Inventive Example 5 but varying only the contents of silver nanoparticles and silver nanoparticle aggregates as shown in Table 9, the dispersion of the paste compositions prepared in the same manner as in item 1. (3) above was measured using a Fineness of Grind Gauge (FOG) device, and the shear strength was measured using a typical die shear measurements in the same manner as that in item 2, and the results thereof are shown in Table 9.

TABLE 9
Evaluation of Physical Properties According
to the Content of Silver Nanoparticles

| | Silver | | Silver Nanoparticle | | Paste | |
|---|---|---|---|---|---|---|
| | Nanoparticles | | Aggregate | | Dispersion | Shear |
| | | Content | | Content | FOG | Strength |
| | Type | (wt %) | Type | (wt %) | (μm) | (MPa) |
| Inventive | Preparation | 3 | Preparation | 74 | 2 | 30.4 |
| Example 43 | Example 1 | | Example 33 | | | |
| Inventive | Preparation | 5 | Preparation | 72 | 2 | 31.2 |
| Example 44 | Example 1 | | Example 33 | | | |
| Inventive | Preparation | 10 | Preparation | 67 | 7 | 30.7 |
| Example 45 | Example 1 | | Example 33 | | | |
| Comparative | Preparation | 20 | Preparation | 57 | 8 | 25.8 |
| Example 17 | Example 1 | | Example 33 | | | |
| Comparative | Preparation | 30 | Preparation | 47 | 7 | 20.4 |
| Example 18 | Example 1 | | Example 33 | | | |
| Comparative | Preparation | 50 | Preparation | 27 | 9 | 16.3 |
| Example 19 | Example 1 | | Example 33 | | | |
| Inventive | Preparation | 3 | Preparation | 74 | 2 | 34.4 |
| Example 46 | Example 2 | | Example 30 | | | |
| Inventive | Preparation | 5 | Preparation | 72 | 2 | 36.3 |
| Example 5 | Example 2 | | Example 30 | | | |
| Inventive | Preparation | 10 | Preparation | 67 | 4 | 31.2 |
| Example 47 | Example 2 | | Example 30 | | | |
| Comparative | Preparation | 20 | Preparation | 57 | 5 | 26.1 |
| Example 20 | Example 2 | | Example 30 | | | |
| Comparative | Preparation | 30 | Preparation | 47 | 7 | 19.3 |
| Example 21 | Example 2 | | Example 30 | | | |
| Comparative | Preparation | 50 | Preparation | 27 | 7 | 15.7 |
| Example 22 | Example 2 | | Example 30 | | | |

As shown in Table 9, when monodisperse silver nanoparticles are included in amounts exceeding the content range of the present disclosure, paste dispersion performance deteriorates and shear strength tends to decrease.

### 5. Evaluation of Physical Properties of Paste Compositions According to the Size of Individual Silver Particles and Aggregates

With respect to the paste composition prepared by varying the sizes of silver nanoparticles and silver nanoparticle aggregates as shown in Table 10 in Inventive Example 5 and Inventive Example 5, among the paste compositions prepared in item 1. (3) above, the dispersion of the paste compositions prepared in the same manner as that in item 1. (3) above was measured using a Fineness of Grind Gauge (FOG) device, and the shear strength was measured using typical die shear measurements as in the same manner as that in item 2 above, and the results thereof are shown in Table 10.

TABLE 10
Evaluation of Physical Properties According to the
Size of Single particles and Aggregate particles

| | Size of | | | |
|---|---|---|---|---|
| | Silver | Size of Silver | Paste | Shear |
| | particles | Nanoparticle | Dispersion | Strength |
| Division | (μm) | Aggregate (μm) | FOG (μm) | (MPa) |
| Comparative | 10 | 0.4 | 13 | 2.7 |
| Example 23 | | | | |
| Comparative | | 1 | 17 | 4.3 |
| Example 24 | | | | |
| Comparative | | 7 | 15 | 3.5 |
| Example 25 | | | | |
| Comparative | | 10 | 18 | 2.6 |
| Example 26 | | | | |
| Comparative | | 20 | 21 | 1.7 |
| Example 27 | | | | |
| Comparative | | 30 | 20 | 2.4 |
| Example 28 | | | | |
| Comparative | | 35 | 19 | 1.3 |
| Example 29 | | | | |
| Inventive | 30 | 0.4 | 4 | 12.7 |
| Example 48 | | | | |
| Inventive | | 1 | 2 | 16.3 |
| Example 49 | | | | |
| Inventive | | 7 | 2 | 20.5 |
| Example 50 | | | | |
| Inventive | | 10 | 4 | 17.6 |
| Example 51 | | | | |
| Inventive | | 20 | 7 | 21.1 |
| Example 52 | | | | |
| Inventive | | 30 | 11 | 18.6 |
| Example 53 | | | | |
| Inventive | | 35 | 10 | 17.4 |
| Example 54 | | | | |
| Inventive | 50 | 0.4 | 2 | 22.7 |
| Example 55 | | | | |
| Inventive | | 1 | 1 | 36.3 |
| Example 5 | | | | |
| Inventive | | 7 | 2 | 30.5 |
| Example 56 | | | | |
| Inventive | | 10 | 4 | 27.6 |
| Example 57 | | | | |
| Inventive | | 20 | 7 | 27.2 |
| Example 58 | | | | |
| Inventive | | 30 | 10 | 24.1 |
| Example 59 | | | | |
| Inventive | | 35 | 8 | 23.1 |
| Example 60 | | | | |
| Inventive | 100 | 0.4 | 3 | 12.4 |
| Example 61 | | | | |
| Inventive | | 1 | 3 | 26.3 |
| Example 62 | | | | |
| Inventive | | 7 | 2 | 20.5 |
| Example 63 | | | | |
| Inventive | | 10 | 7 | 27.6 |
| Example 64 | | | | |
| Inventive | | 20 | 10 | 17.2 |
| Example 65 | | | | |
| Inventive | | 30 | 12 | 14.1 |
| Example 66 | | | | |
| Inventive | | 35 | 11 | 13.1 |
| Example 67 | | | | |
| Inventive | 200 | 0.4 | 5 | 12.7 |
| Example 68 | | | | |
| Inventive | | 1 | 7 | 14.3 |
| Example 69 | | | | |
| Inventive | | 7 | 5 | 13.5 |
| Example 70 | | | | |
| Inventive | | 10 | 8 | 12.6 |
| Example 71 | | | | |
| Inventive | | 20 | 11 | 11.7 |
| Example 72 | | | | |
| Inventive | | 30 | 10 | 12.4 |
| Example 73 | | | | |
| Inventive | | 35 | 9 | 11.3 |
| Example 74 | | | | |
| Comparative | 300 | 0.4 | 8 | 1.5 |
| Example 30 | | | | |
| Comparative | | 1 | 7 | 2.1 |
| Example 31 | | | | |
| Comparative | | 7 | 10 | 2.5 |
| Example 32 | | | | |
| Comparative | | 10 | 8 | 1.6 |
| Example 33 | | | | |
| Comparative | | 20 | 11 | 2.2 |
| Example 34 | | | | |
| Comparative | | 30 | 10 | 1.4 |
| Example 35 | | | | |
| Comparative | | 35 | 9 | 1.3 |
| Example 36 | | | | |

As illustrated in Table 10, it may be confirmed that when the particle size falls below the particle size range of the present disclosure, because the surface energy of the nanoparticles increases, the nanoparticles aggregate to degrade dispersion performance, resulting in lower shear strength, and when the particle size thereof exceeds and deviates from the range, the specific surface area of the nanoparticles decreases, resulting in lower shear strength. Furthermore, when the size of the silver nanoparticles aggregates is less than 0.5 μm, this exhibit surface energy similar to that of individual silver nanoparticles, resulting in lower dispersion performance and lower shear strength, and when the size of the silver nanoparticle aggregates exceeds 30 μm, the activation energy of the nanoparticles decreases, resulting in lower shear strength.

### 6. Evaluation of the Physical Properties of Paste Compositions According to the Size of Individual Silver Particles

With respect to Example 5, which used the silver nanoparticle aggregates of Preparation Example 30, obtained by surface-treating the silver nanoparticle aggregates obtained in Preparation Example 16 with oleic acid, among the paste compositions prepared in item 1. (3) above, and Preparation Examples 8-1, 21-1 and 22-1, having silver nanoparticle aggregates prepared by surface-treating the silver nanoparticle aggregates of Preparation Examples 8, 21, and 22 with oleic acid under the same conditions as Preparation Example 19 instead of Preparation Example 16, and paste compositions prepared using micro-sized single powder particles instead of nanoparticle aggregates, the dispersity of the paste compositions prepared in the same manner as that in item 1. (3) above was measured using a Fineness of Grind Gauge (FOG) device and are shown, and the shear strength was measured using typical Die shear measurements in the same manner as that in item 2 above, and the results thereof are shown in Table 10 below. In this case, the term “individual particle(s)” or “single particle(s)” encompasses both nano- and micro-sized powder particles.

TABLE 11
Evaluation of physical properties according to single particle size

| | | | Paste | Shear |
|---|---|---|---|---|
| | | Particle | Dispersity | Strength |
| | Powder Shape | size (μm) | FOG (μm) | (MPa) |
| Inventive | Preparation | 0.92 | 4 | 32.7 |
| Example 75 | Example 8-1 | | | |
| Inventive | Preparation | 1.04 | 2 | 36.3 |
| Example 5 | Example 30 | | | |
| Inventive | Preparation | 1.37 | 2 | 30.5 |
| Example 76 | Example 21-1 | | | |
| Inventive | Preparation | 1.55 | 4 | 27.6 |
| Example 77 | Example 22-1 | | | |
| Comparative | Micro-single | 0.5 | 1 | 7 |
| Example 37 | particle | | | |
| Comparative | Micro-single | 1 | 2 | 4 |
| Example 38 | particle | | | |
| Comparative | Micro-single | 3 | 2 | 3 |
| Example 39 | particle | | | |
| Comparative | Micro-single | 5 | 3 | 1 |
| Example 40 | particle | | | |

As may be seen in Table 11 above, when the silver nanoparticle aggregates of the present disclosure are used along with individual silver nanoparticles, this exhibit significantly superior shear strength as compared to when micro-single particles of a similar size are used instead of the silver nanoparticle aggregates.

Although the example embodiment of the present disclosure has been described in detail above, it will be obvious to those skilled in the art that the scope of the present disclosure is not limited thereto, and various modifications and variation may be made without departing from the technical concept of the present disclosure described in the claims.

What is claimed is:

1. A paste composition for pressureless sinter bonding, comprising:
silver nanoparticles;
silver nanoparticle aggregates; and
a mixed solvent including an alcohol-based solvent and an ether-based solvent.

2. The paste composition for pressureless sinter bonding according to claim 1, comprising: based on a total weight of the paste composition,
0.1 to 10 wt % of silver nanoparticles having a particle size of 10 nm to 300 nm;
60 to 80 wt % of silver nanoparticle aggregates having a particle size of 0.5 μm to 30 μm; and
a remaining mixed solvent including an alcohol-based solvent and an ether-based solvent in a weight ratio of 1:3 to 3:1.

3. The paste composition for pressureless sinter bonding according to claim 1, wherein the mixed solvent further includes an acetate-based solvent.

4. The paste composition for pressureless sinter bonding according to claim 3, wherein the mixed solvent includes an alcohol-based solvent, an ether-based solvent, and an acetate-based solvent in a weight ratio of 80 to 98:1 to 10:1 to 10.

5. The paste composition for pressureless sinter bonding according to claim 1, wherein the silver nanoparticle aggregates are obtained by reacting the silver nanoparticles at 50 to 100° C. under nitrate salt for 1 to 3 hours.

6. The paste composition for pressureless sinter bonding according to claim 1, wherein the silver nanoparticle aggregates are surface-treated with a surface treatment agent including at least one component selected from a group consisting of fatty acids having a carbon chain length of C₅ to C₂₆, long-chain alkanethiols, and amine derivatives, and a specific surface area is greater than 1 m²/g and less than or equal to 2 m²/g.

7. The paste composition for pressureless sinter bonding according to claim 6, wherein the surface treatment agent includes at least one component selected from the group consisting of C₁₀ to C₂₂ fatty acids, alkanethiols, and aliphatic primary amines.

8. The paste composition for pressureless sinter bonding according to claim 1, wherein the alcohol-based solvent is at least one selected from α-terpineol, 1,2-propanediol, 1,3-butanediol, 2-methyl-1,3-propanediol, 1-decanol, 1-octanol, propylene glycol, glycerol, trimethylolpropane, ethylene glycol, diethylene glycol, triethylene glycol, cyclohexanol, lauryl alcohol, oleyl alcohol, nonyl alcohol and dodecanol.

9. The paste composition for pressureless sinter bonding according to claim 1, wherein the ether solvent is at least one selected from diethylene glycol butyl ether, diethylene glycol mono-n-hexyl ether, diethylene glycol monomethyl ether, diethylene glycol monophenyl ether, tripropylene glycol butyl ether, diethylene glycol dibutyl ether, triethylene glycol monobutyl ether, diethylene glycol monobenzyl ether, diethylene glycol butyl methyl ether, triethylene glycol dimethyl ether, ethylene glycol monophenyl ether, isopropyl ether, and tetraethylene glycol dimethyl ether.

10. The paste composition for pressureless sinter bonding according to claim 3, wherein the acetate-based solvent is at least one selected from propylene glycol diacetate, dipropylene glycol methyl ether acetate, propylene glycol monomethyl ether acetate, butyl acetate, methyl acetate, ethyl acetate, 4-tert-butylcyclohexyl acetate, 2-butoxyethanol acetate, and ethylene glycol monobutyl ether acetate.

11. The paste composition for pressureless sinter bonding according to claim 1, further comprising:
at least one thickener selected from a group consisting of an epoxy and curing agent mixture, an inorganic thixotropic agent, and an organic thixotropic agent.

12. The paste composition for pressureless sinter bonding according to claim 11, wherein the thickener is included in an amount of 0.1 wt % to 15 wt % based on the total weight of the paste composition.

13. The paste composition for pressureless sinter bonding according to claim 1, further comprising:
at least one additive selected from a group consisting of an organic dispersant, a nonionic surfactant, and an aliphatic compound.

14. The paste composition for pressureless sinter bonding according to claim 13, wherein the aliphatic compound is at least one selected from the group consisting of palmitic acid, malonic acid, and oleic acid.

15. The paste composition for pressureless sinter bonding according to claim 13, wherein the additive is included in an amount of 0.1 wt % to 5 wt % based on the total weight of the paste composition.

16. The paste composition for pressureless sinter bonding according to claim 1, further comprising one or more metal powder particles selected from copper (Cu), silver-coated copper (Ag-Coated Cu), gold (Au), platinum (Pt), nickel (Ni), tin (Sn), aluminum (Al), zinc (Zn), bismuth (Bi), indium (In), phosphorus (P), and silicon (Si), or two or more alloy powder particles selected therefrom.

17. A bonding method comprising the operations of applying a paste composition for pressureless sinter bonding according to claim 1 to a bonding surface and heating a bonding object at a temperature of 150 to 300° C. under an atmospheric pressure of 1 atm while bonding the bonding object to the bonding surface.

18. An electronic component manufactured by bonding using a paste composition for pressureless sinter bonding according to claim 1.
